(19) United States
(12) Patent Application Publication
(10) Pub. No.: US 2012/0273883 A1
(43) Pub. Date: Nov. 1, 2012

(54) HIGH VOLTAGE DEVICES AND METHODS FOR FORMING THE SAME

(75) Inventors: Shiang-Yu CHEN, Hsinchu (TW); Chi-Chih CHEN, Hsinchu (TW); Kuo-Ming WU, Hsinchu (TW)

(73) Assignee: TAIWAN SEMICONDUCTOR MANUFACTURING COMPANY, LTD., Hsinchu (TW)

(21) Appl. No.: 13/096,117

(22) Filed: Apr. 28, 2011

(51) Int. Cl. H01L 29/78; H01L 21/336

(52) U.S. Cl. 257/339; 438/289; 257/E29.255; 257/E21.435

(57) ABSTRACT

A high voltage (HV) device includes a gate dielectric structure over a substrate. The gate dielectric structure has a first portion and a second portion. The first portion has a first thickness and is disposed over a first well region of a first dopant type in the substrate. The second portion has a second thickness and is disposed over a second well region of a second dopant type. The first thickness is larger than the second thickness. An isolation structure is disposed between the gate dielectric structure and a drain region disposed within the first well region. A gate electrode is disposed over the gate dielectric structure.

### CROSS-REFERENCES TO RELATED APPLICATIONS

The present application is a related to U.S. application Ser. No. 12/792,055, entitled “HIGH VOLTAGE DEVICES, SYSTEMS, AND METHODS FOR FORMING THE HIGH VOLTAGE DEVICES” filed on Jun. 6, 2010 (Attorney Docket No. TSMC2009-0561/T5057-B126U), which is incorporated herein by reference.

### TECHNICAL FIELD

The present disclosure relates generally to the field of semiconductor circuits and, more particularly, to high voltage devices, systems, and methods for forming the high voltage devices.

### BACKGROUND

The demand for compact, portable, and low cost consumer electronic devices has driven electronics manufacturers to develop and manufacture integrated circuits (IC) that operate with low power supply voltages resulting in low power consumption. There may be components of the devices that require higher voltages than the low power supply voltage. For example, liquid crystal display (LCD) drivers may use high voltage (HV) MOS transistors for driving pixels of LCD.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the numbers and dimensions of the various features may be arbitrarily increased or reduced for clarity of discussion.

FIG. 1A is a schematic cross-sectional view of an exemplary high voltage (HV) device.

FIG. 1B shows simulation results of breakdown voltages of conventional HV devices and the HV device.

FIG. 2 is a flowchart of an exemplary method of forming an HV device.

FIG. 3 is a top view showing various mask layers that are overlapped for forming an HV device.

FIGS. 4A-4H are schematic cross-sectional views of the HV device taken along the sectional line 4-4 of FIG. 3 during various fabrication stages.

### DETAILED DESCRIPTION

An HV device known to the applicants uses a thick gate dielectric layer abutting a local oxidation of silicon (LOCOS) structure under a gate electrode. Applicants found that the HV device can sustain a high breakdown voltage between the gate and drain of the HV device during an off-state mode. However, a high driving voltage is used to drive the HV device due to its thick gate dielectric layer.

Another HV device known to the applicants uses a thin gate dielectric layer abutting a local oxidation of silicon (LOCOS) structure under a gate electrode. Though the driving power is lowered, Applicants found that this HV device has a lower breakdown voltage between the gate and drain of the HV device during an off-state mode.

Another HV device known to the applicants uses a dual-thickness gate dielectric layer. A thin oxide is disposed over a channel region and a thick oxide is disposed over a drift region. The thick oxide is separated from a drain of the HV device by a predetermined distance. No LOCOS structure is disposed between the thick oxide and the drain of the HV device. Applicants found that the third HV device still has a breakdown voltage that is lower than that of the first HV device.

From the foregoing, new HV device structures and methods of forming the same are desired.

It is understood that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “below,” “up,” “down,” “top,” “bottom,” etc. as well as derivatives thereof (e.g., “horizontally,” “downwardly,” “upwardly,” etc.) are used for ease of the present disclosure of one feature relationship to another feature. The spatially relative terms are intended to cover different orientations of the device including the features.

In some embodiments, an HV device can include a gate dielectric structure over a substrate. The gate dielectric structure has a first portion and a second portion. The first portion has a first thickness and is over a first well region of a first dopant type in the substrate. The second portion has a second thickness and is over a second well region of a second dopant type. The first thickness is larger than the second thickness. An isolation structure is disposed between the gate dielectric structure and a drain region disposed within the first well region. A gate electrode is disposed over the gate dielectric structure.

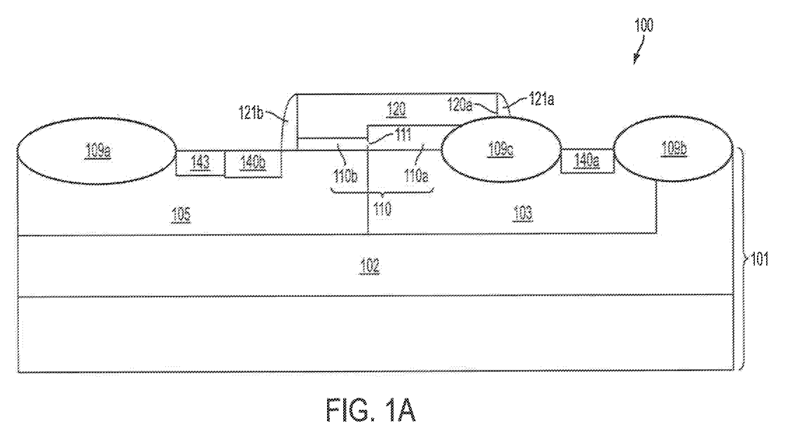

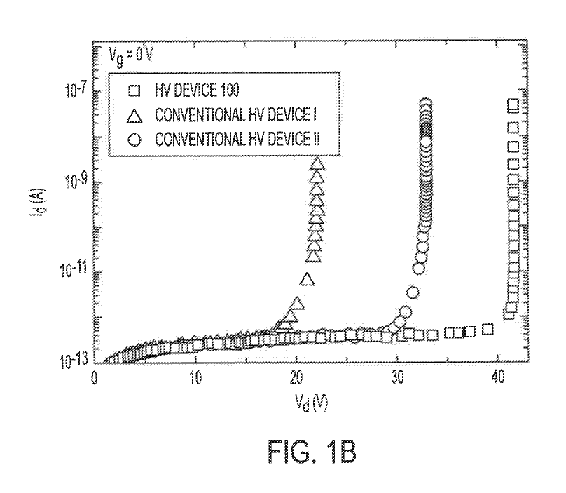

For example, FIG. 1A is a schematic cross-sectional view of an exemplary high voltage (HV) device. In FIG. 1A, an HV device 100 can be referred to as an HV laterally diffused MOS (HV LDMOS) transistor, an HV extended drain MOS (HV EDMOS) transistor, or one of other HV devices. Referring to FIG. 1A, the HV device 100 can include a substrate 101. In some embodiments, the substrate 101 can include an elementary semiconductor including silicon or germanium in crystal, polycrystalline, or an amorphous structure; a compound semiconductor including silicon carbide, gallium arsenide, gallium phosphide, indium phosphide, indium arsenide, and indium antimonide; an alloy semiconductor including SiGe, GaAsP, AlInAs, AlGaAs, GaInAs, GaInP, and GaInAsP; any other suitable material; or combinations thereof. In one embodiment, the alloy semiconductor substrate may have a gradient SiGe feature in which the Si and Ge composition change from one ratio at one location to another ratio at another location of the gradient SiGe feature. In another embodiment, the alloy SiGe is formed over a silicon substrate. In another embodiment, a SiGe substrate is strained. Furthermore, the semiconductor substrate may be a semiconductor on insulator, such as silicon on insulator (SOI), or a thin film transistor (TFT). In some examples, the semiconductor substrate 101 may include a doped epitaxial (epi) layer, e.g., a doped epi layer 102.

Referring to FIG. 1A, the HV device 100 can include a well region 103 of a first dopant type, e.g., an n-type dopant, in the substrate 101. In some embodiments, the well region 103 can be referred to as a high-voltage well region, e.g., an HV N-type well (HVNW) region. In other embodiments, the well region 103 can have a dopant type opposite to that of the doped epi layer 102. In still other embodiments, the well region 103 can have a dopant concentration that is higher than that of the doped epi layer 102.

Referring to FIG. 1A, the HV device 100 can include a well region 105 of a second dopant type, e.g., p-type dopant, in the substrate 101. In some embodiments referring to an N-type HV device, the well region 105 can have a p-type dopant that is opposite to that of the well region 103. In some other embodiments, the well region 105 can be referred to as a high-voltage well region, e.g., an HV P-type well (HVPW) region. The well region 105 can have a dopant concentration that is higher than that of the doped epi layer 102.

Referring to FIG. 1A, the HV device 100 can include a gate dielectric structure 110. The gate dielectric structure 110 can have a first portion, e.g., a portion 110a and a second portion, e.g., a portion 110b. The portion 110a can be disposed over the well region 103. The portion 110b can be disposed over the well region 105. An interface 111 is between the portions 110a and 110b. In some embodiments, the interface 111 can be substantially aligned with an interface between the well regions 103 and 105 as shown in FIG. 1A. In other embodiments, the interface 111 can be over the well region 103 or 105.

In some embodiments, the portion 110a is disposed over a channel region (not labeled) in the well region 105 of the HV device 100. The portion 110b is disposed over a drift region (not labeled) in the well region 103 of the HV device 100. In some embodiments, the portion 110a can be thicker than the second portion 110b. In some embodiments, the portion 110a can have a thickness ranging from about 600 Angstroms (Å) to about 690 Å and the portion 110b can have a thickness ranging from about 100 Å and about 150 Å. It is noted that the thicknesses of the portions 110a and 110b described above are merely exemplary. The thicknesses of the portions 110a and 110b may vary depending on the technology node used to make the HV device 100 and/or the breakdown voltage of the HV device 100.

In some embodiments, each of the portions 110a and 110 of the gate dielectric structure 110 can be a single layer or a multi-layer structure. In embodiments for multi-layer structures, the gate dielectric structure 110 can include an interfacial layer and a high dielectric constant (high-k) dielectric layer. The interfacial layer can include dielectric material, such as silicon oxide, silicon nitride, silicon oxynitride, other dielectric material, and/or the combinations thereof. The high-k dielectric layer can include high-k dielectric materials such as HfO₂, HfSiO, HfSiON, HfTaO, HfTiO, HfZrO, other suitable high-k dielectric materials, and/or combinations thereof. The high-k material may further be selected from metal oxides, metal nitrides, metal silicates, transition metal-oxides, transition metal-nitrides, transition metal-silicates, oxynitrides of metals, metal aluminates, zirconium silicate, zirconium aluminate, silicon oxide, silicon nitride, silicon oxynitride, zirconium oxide, titanium oxide, aluminum oxide, hafnium dioxide-alumina alloy, other suitable materials, and/or combinations thereof.

In some embodiments, at least one isolation structure, e.g., isolation structures 109a and 109b, can be disposed adjacent to the surface of the substrate 101 for isolating the HV device 100 from other devices (not shown) or guard rings. The isolation structures 109a and 109b can include a structure of a local oxidation of silicon (LOCOS), a shallow trench isolation (STI) structure, and/or any suitable isolation structure. Referring to FIG. 1A, an isolation structure 109c can be disposed in the well region 103. The isolation structure 109c can be disposed between the gate dielectric structure 110 and a source/drain (S/D) region, e.g., a drain region 140a of the HV device 100.

Referring to FIG. 1A, the HV device 100 can include a gate electrode 120. The gate electrode 120 can be disposed over the gate dielectric structure 110. The gate electrode 120 can have an edge 120a. In some embodiments, the gate electrode 120 can at least partially extend over the isolation structure 109c. In other embodiments, the edge 120a of the gate electrode 120 can reach the central region of the isolation structure 109c.

In some embodiments, the gate electrode 120 can include polysilicon, silicon-germanium, a metallic material including metal compounds, such as Mo, Cu, W, Ti, Ta, TiN, TaN, NiSi, CoSi, and/or other suitable conductive materials. In some other embodiments, the gate electrode 120 can include a work function metal layer such that it provides an N-metal work function or P-metal work function of a metal gate. P-type work function materials include compositions such as ruthenium, palladium, platinum, cobalt, nickel, and conductive metal oxides, and/or other suitable materials. N-type metal materials include compositions such as hafnium, zirconium, titanium, tantalum, aluminum, metal carbides (e.g., hafnium carbide, zirconium carbide, titanium carbide, aluminum carbide), aluminides, and/or other suitable materials.

In some embodiments, spacers 121a and 121b can be disposed on sidewalls of the gate electrode 120. The spacers 121a and 121b include at least one material, e.g., oxide, nitride, oxynitride, other dielectric material, or any combinations thereof.

Referring to FIG. 1A, the HV device 100 can include at least one source/drain (S/D) region, e.g., a drain region 140a and a source region 140b. The drain region 140a can be disposed in the well region 103. The source region 140b can be disposed in the well region 105. In some embodiments, the drain region 140a and the source region 140b can include dopants. In some embodiments referring to an N-type HV device, the drain region 140a and the source region 140b can have dopants such as Arsenic (As), Phosphorus (P), another group V element, or any combinations thereof. For other embodiments referring to a P-type HV device, the drain region 140a and the source region 140b can have dopants such as boron (B), another group III element, or any combinations thereof.

In some embodiments, each of the drain region 140a and the source region 140b can include a silicide structure (not shown). The silicide structure may comprise materials such as nickel silicide (NiSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), other suitable materials, and/or combinations thereof.

In some embodiments, the HV device 100 can include a doped region 143 disposed adjacent to the source region 140b. The doped region 143 is configured to electrically couple a voltage to a bulk, e.g., the well region 105, of the HV device 100. The doped region 143 and the well region 105 can have the same dopant type. In some embodiments referring to an N-type HV device, the doped region 143 can have dopants such as boron (B), another group III element, or any combinations thereof.

In some embodiments, at least one dielectric layer (not shown) can be disposed over the gate electrode 120. The at least one dielectric layer may include materials such as silicon oxide, silicon nitride, silicon oxynitride, one or more low dielectric constant (low-k) dielectric materials, one or more ultra low-k dielectric materials, or any combinations thereof. In some embodiments, at least one interconnect structure, e.g., contact plugs, via plugs and/or metallic lines (not shown), can be disposed within and/or over the at least one dielectric layer. The interconnect structure can be made of materials such as tungsten, aluminum, copper, titanium, tantalum, titanium nitride, tantalum nitride, nickel silicide, cobalt silicide, other proper conductive materials, and/or combinations thereof.

As noted, the isolation structure 109c is disposed between the gate dielectric structure 110 and the drain region 140a. It is unexpectedly found that the isolation structure 109c functions with the portion 110a to enhance the gate-to-drain breakdown voltage (BVdss) of the HV device 100 during an off-state operation. For example, FIG. 1B shows simulation results of breakdown voltages of HV devices known to the applicants and the HV device 100. In FIG. 1B, an HV device I has a single thin gate dielectric layer covering a channel region in a p-well region and a drift region in an n-well region. The single thin gate dielectric layer abuts a LOCOS structure. The HV device II has a multi-thickness gate dielectric layer. A thin gate dielectric portion covers a channel region in a p-well region and a thick dielectric portion covers a drift region in an n-well region. The thick dielectric layer portion is separated from a drain of the HV device II without any isolation structure therebetween. As shown in FIG. 1B, the HV device I can sustain a breakdown voltage BVdss of about 20 V. The HV device II can sustain a breakdown voltage BVdss of about 30 V. The HV device 100 can sustain a breakdown voltage BVdss of about 40 V or more, which outperforms the HV devices I and II.

Following are descriptions regarding exemplary methods of forming HV devices. In some embodiments, a method of forming an HV device can include forming a gate dielectric structure over a substrate. The gate dielectric structure can have a first portion and a second portion. The first portion can have a first thickness and be over a first well region of a first dopant type in the substrate. The second portion can have a second thickness and be over a second well region of a second dopant type. The first thickness is larger than the second thickness. The method can include forming an isolation structure between the gate dielectric structure and a drain region disposed within the first well region. The method can also include forming a gate electrode over the gate dielectric structure.

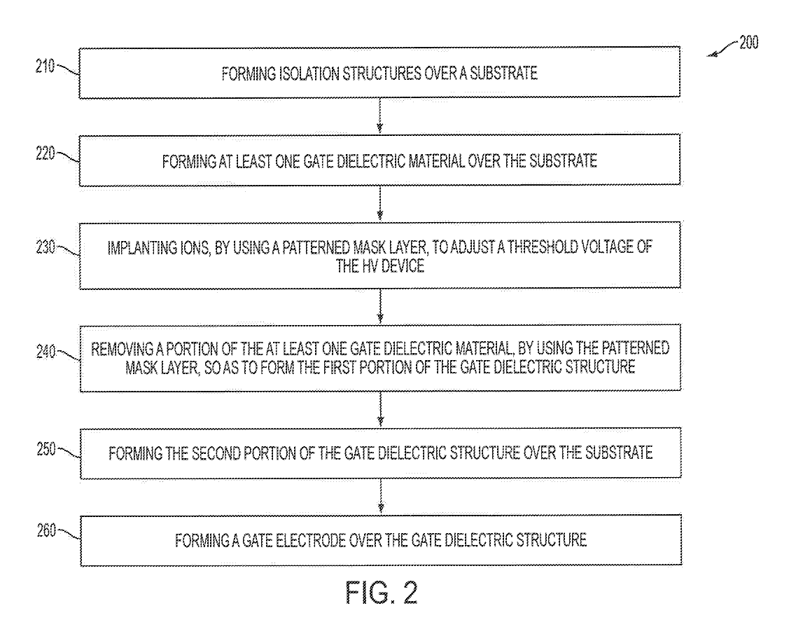

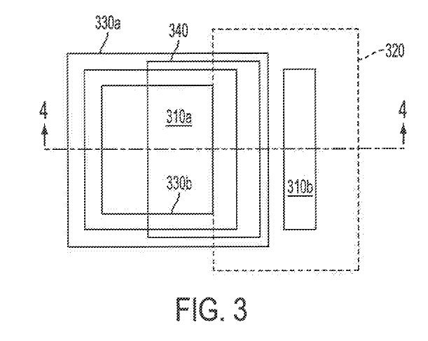

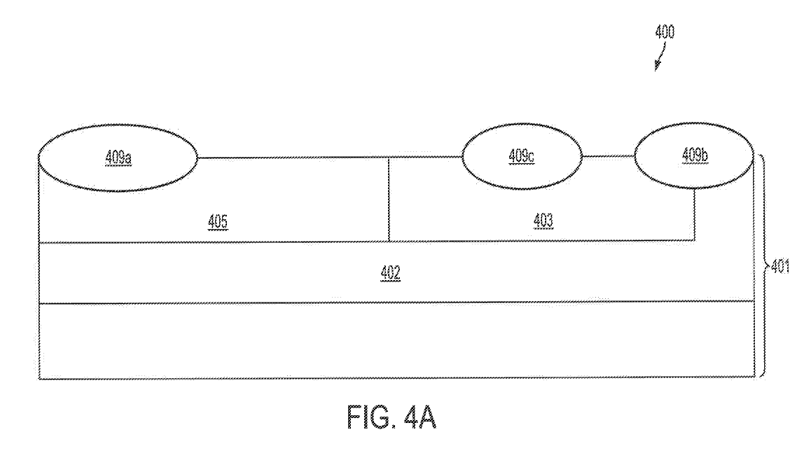

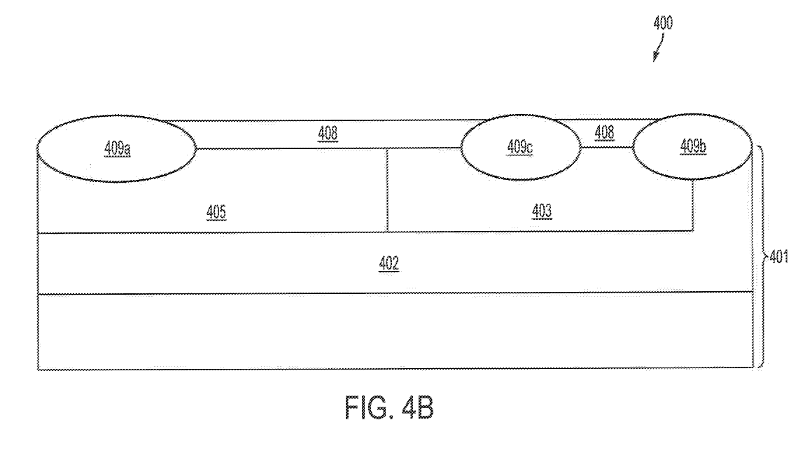

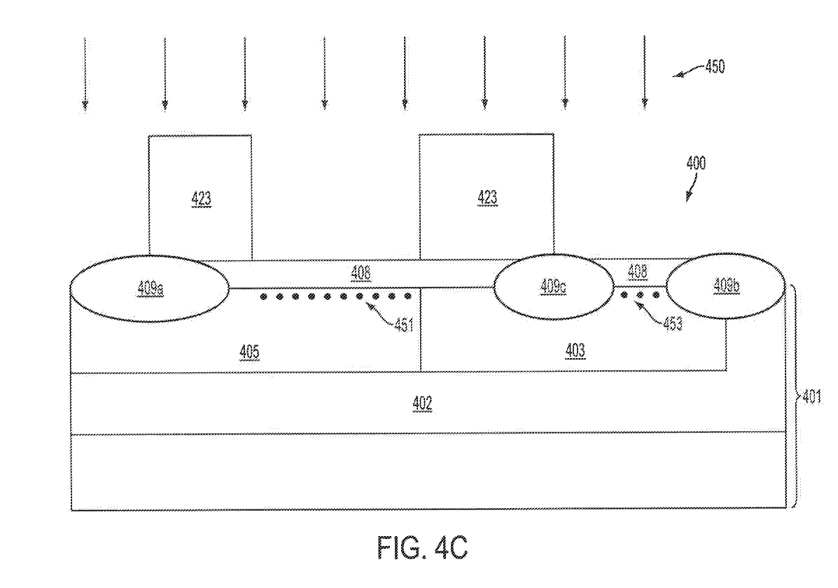

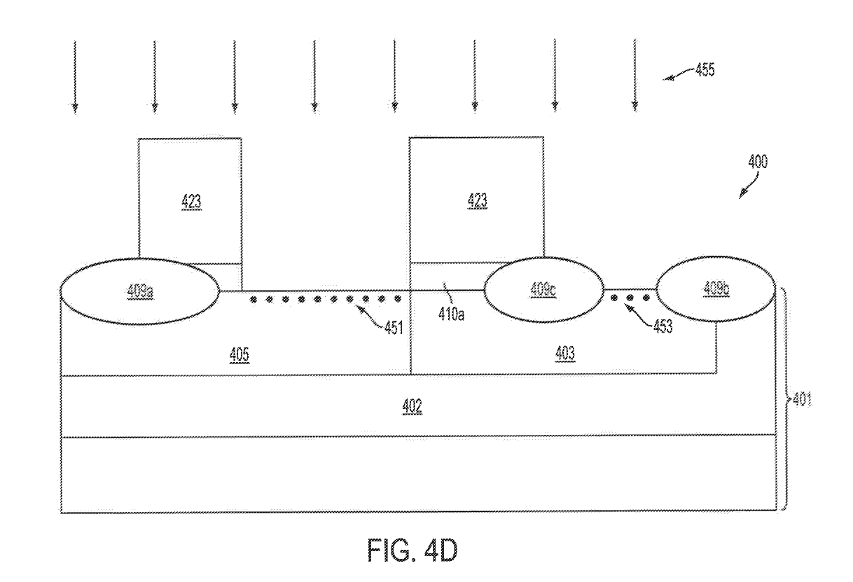

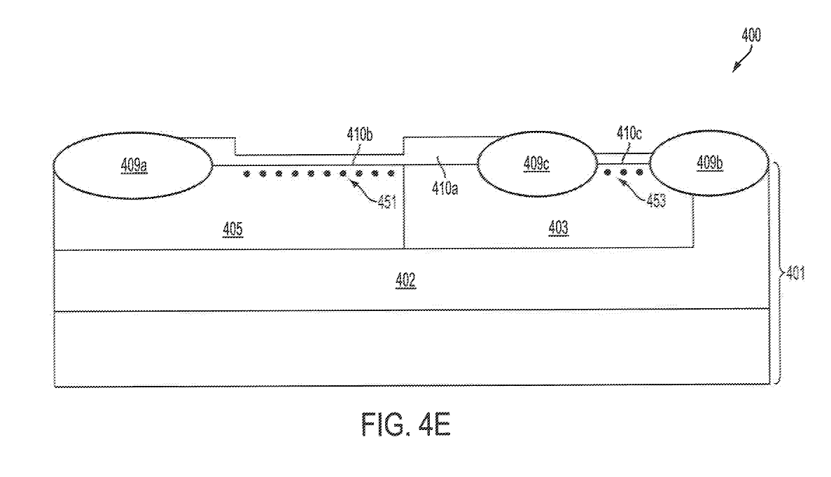

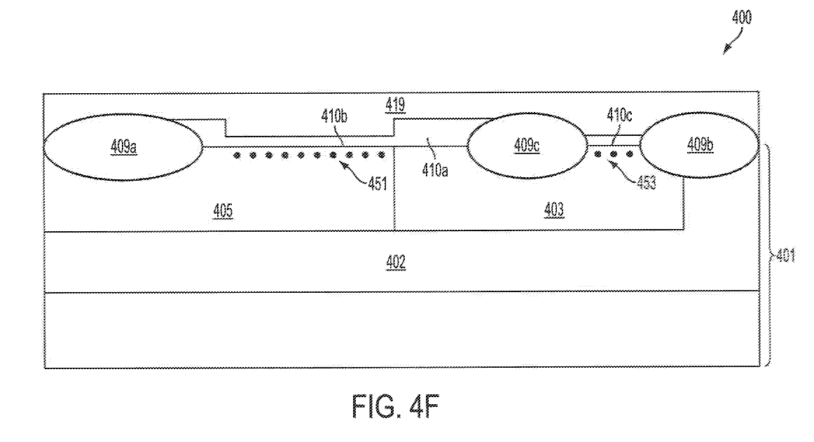

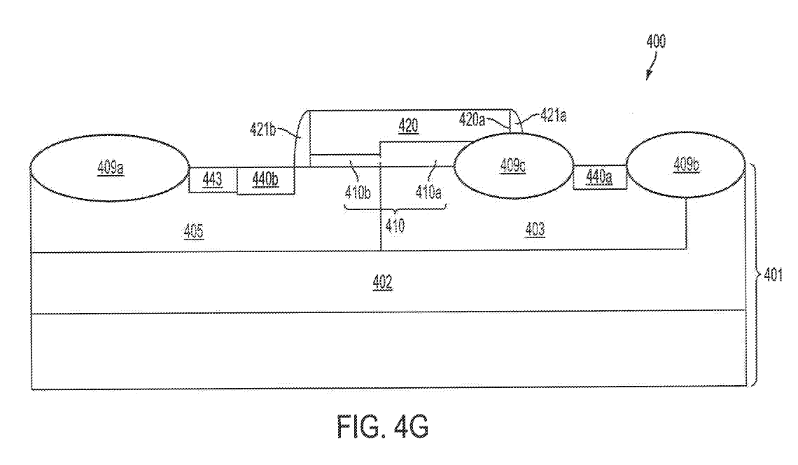

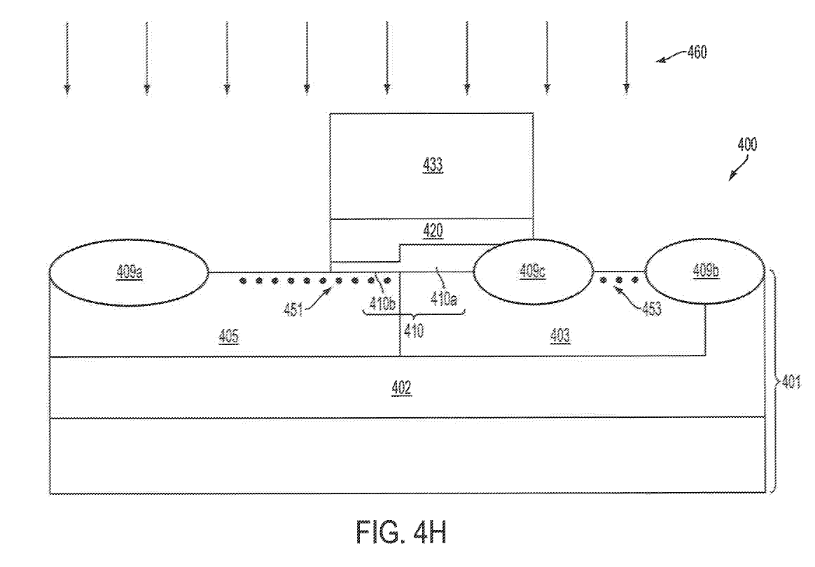

For example, FIG. 2 is a flowchart of an exemplary method of forming an HV device. FIG. 3 is a top view showing various mask layers that are overlapped for forming the HV device. FIGS. 4A-4H are schematic cross-sectional views of the HV device taken along the sectional line 4-4 of FIG. 3 during various fabrication stages. Items of FIGS. 4A-4H that are the same or similar items in FIG. 1 are indicated by the same reference numerals, increased by 300. It is understood that methods of FIGS. 2 and 4A-4H have been simplified for a better understanding of the concepts of the present disclosure. Accordingly, it should be noted that additional processes may be provided before, during, and after the methods of FIGS. 2 and/or 4A-4H, and that some other processes may only be briefly described herein.

Referring to FIG. 2, a method 200 of forming an HV device includes forming isolation structures over a substrate (block 210). For example, referring to FIG. 4A a substrate 401 having a doped epi layer 402 is provided. Isolation structures 409a-409c can be formed on the surface of the substrate 401. In some embodiments, the isolation structures 409a-409c can be formed by a LOCOS or STI process using an oxide definition (OD) mask layer. The OD mask layer can include OD regions 310a and 310b as shown in FIG. 3. On the OD mask layer, the OD regions 310a and 310b are dark and their patterns are transferred to at least one pad layer (not shown) that covers areas among the isolation structures 409a-409c. As one example, the formation of the isolation structures 409a-409c may include patterning the substrate 401 by a photolithography process, etching a trench in the substrate (for example, by using a dry etching, wet etching, and/or plasma etching process), and filling the trench (for example, by using a chemical vapor deposition process) with a dielectric material. In some embodiments, the filled trench may have a multi-layer structure such as a thermal oxide liner layer filled with silicon nitride or silicon oxide.

In some embodiments, before or after the LOCOS or STI process well regions 403 and 405 can be formed within the substrate 401. In some embodiments, the well region 403, e.g., an N-well region, can be formed by an ion implantation process (not shown) using an N-well mask layer. The N-well mask layer can have a well region 320 as shown in FIG. 3. On the N-well mask layer, the well region 320 is clear and its pattern is transferred to a photoresist layer (not shown) that opens over the area of the well region 403. The ion implantation process implants ions through the opening of the photoresist layer.

In some embodiments, the well region 405, e.g., a P-well region, can be formed by another ion implantation process (not shown) using a P-well mask layer. The P-well mask layer can also have the well region 320 as shown in FIG. 3. In contrast to the N-well mask layer for forming the well region 403, the well region 320 on the P-well mask layer for forming the well region 405 is dark and its pattern is transferred to another photoresist layer (not shown) that covers the well region 403. The ion implantation process implants ions into the substrate except the well region 403.

Referring to FIG. 2, the method 200 includes forming at least one gate dielectric material over the substrate (block 220). For example, at least one gate dielectric material, e.g., a gate dielectric material 408, can be formed over the substrate 401 as shown in FIG. 4B. In some embodiments, the gate dielectric material 408 can be formed among the isolation structures 409a-409c and does not cover the isolation structures 409a-409c. In other embodiments, the gate dielectric material 408 can be formed and substantially conformal over the substrate 401 and the isolation structures 409a-409c. In some embodiments, the gate dielectric material 408 may be formed by any suitable process, such as atomic layer deposition (ALD), chemical vapor deposition (CVD), wet oxidation, physical vapor deposition (PVD), remote plasma CVD (RPCVD), plasma enhanced CVD (PECVD), metal organic CVD (MOCVD), sputtering, plating, other suitable processes, and/or combinations thereof.

Referring to FIG. 2, the method 200 includes implanting ions, by using a patterned mask layer, to adjust a threshold voltage of the HV device (block 230). For example, a patterned mask layer 423 can be formed over the gate dielectric material 408 as shown in FIG. 4C. In some embodiment's, a patterned photoresist layer, e.g., the patterned mask layer 423, can be transferred from an HV oxide mask layer. In FIG. 3, the HV oxide mask layer includes a region (not labeled) between blocks 330a and 330b. On the HV oxide mask layer, the region between blocks 330a and 330b is dark and its pattern is transferred to the patterned mask layer 423 (shown in FIG. 4C).

Referring again to FIG. 4C, the patterned mask layer 423 is used as an implantation mask. For example, an ion implantation process 450 implants ions into regions 451 and 453 in the substrate 401 that are not covered by the patterned mask layer 423. In some embodiments forming an N-type HV device, ions in the regions 451 and 453 can be boron (B), another group III element, or any combinations thereof. Ions in the region 451 are provided to adjust a threshold voltage of the HV device 400.

Referring again to FIG. 2, the method 200 includes removing a portion of the at least one gate dielectric material, by using the patterned mask layer, so as to form the first portion of the gate dielectric structure (block 240). For example, a removal process 455, using the patterned mask layer 423, removes portions of the gate dielectric material 408 as shown in FIG. 4D. In some embodiments, the removal process 455 can expose portions of the substrate 401 that are not covered by the patterned mask layer 423. The removal process 455 can include, for example, a dry etch process and/or a wet etch process. The remaining portion of the gate dielectric material 408 that is covered by the patterned mask layer 423 is referred to as a portion 410a. The remaining portions in the regions 451 and 453 of the gate dielectric material 408 that are not covered by the patterned mask layer 423 are referred to as portions 410b and 410c, respectively. After the removal process 455, the patterned mask layer 423 is removed. It is noted that because the patterned mask layer 423 is used in both of the ion implantation process 450 and the removal process 455, the process cycle time and/or cost can be reduced.

Referring to FIG. 2, the method 200 includes forming the second portion of the gate dielectric structure over the substrate (block 250). For example, portions 410b and 410c can be formed over the substrate 401 as shown in FIG. 4E. In some embodiments, the portions 410b and 410c can be formed on the exposed regions of the substrate 401. The portions 410b and 410c can be made by any suitable process, such as atomic layer deposition (ALD), chemical vapor deposition (CVD), wet oxidation, physical vapor deposition (PVD), remote plasma CVD (RPCVD), plasma enhanced CVD (PECVD), metal organic CVD (MOCVD), sputtering, plating, other suitable processes, and/or combinations thereof. Referring to FIG. 2, the method 200 includes forming a gate electrode over the gate dielectric structure (block 260). For example, a gate electrode material 419 can be formed over the isolation structures 409a-409c and portions 410a-410c as shown in FIG. 4F. In some embodiments, the gate electrode material 419 can be formed and substantially conformal over the isolation structures 409a-409c and portions 410a-410c as shown in FIG. 4F. The gate electrode material 419 can be formed by any suitable process, such as atomic layer deposition (ALD), chemical vapor deposition (CVD), wet oxidation, physical vapor deposition (PVD), remote plasma CVD (RPCVD), plasma enhanced CVD (PECVD), metal organic CVD (MOCVD), sputtering, plating, other suitable processes, and/or combinations thereof. In some embodiments, a silicide structure (not shown) can be formed over the gate electrode 419. The salicidation process may cause a deposited metallic material to react with the gate electrode at an elevated temperature that is selected based on the specific material or materials. This is also referred to as annealing, which may include a rapid thermal process (RTP). The reacted silicide may require a one-step RTP or multiple-step RTPs.

Referring to FIG. 4G, the block 260 shown in FIG. 2 can include an etch process 460. The etch process 460, using a patterned mask layer 433, removes a portion of the gate electrode material 419, a part of the portion 410b and the portion 410c. The remaining portion of the gate electrode material 419 is referred to as a gate electrode 420. The patterned mask layer 433 can be transferred from a gate mask layer shown in FIG. 3. In FIG. 3, the mask layer includes a region 340. On the gate mask layer, the region 340 is dark and its pattern is transferred to the patterned mask layer 433 (shown in FIG. 4G). Referring again to FIG. 4G, the portions 410a and 410b that are covered by the patterned mask layer 433 can be referred to as a gate dielectric structure 410. As shown in FIG. 4G, the portion 410a is thicker than the portion 410b. The isolation structure 409c is thicker than the portion 410a.

Referring to FIG. 4H, spacers 421a and 421b can be formed on sidewalls of the gate electrode 420. The spacers 421a and 421b may be formed by depositing a dielectric material by CVD, ALD, PVD, and/or other suitable processes. The dielectric material is then subjected to an etching process so as to form the spacers 421a and 421b.

Referring again to FIG. 4H, S/D regions, e.g., a drain region 440a and a source region 440b can be formed within the well regions 403 and 405, respectively. The drain region 440a and the source region 440b can be formed by any suitable process, such as ion implantation and/or a rapid thermal process (RTP) to activate the doped regions. It is noted that the ions of the S/D implantation can compensate for the ions that were previously doped in the region 453 by the ion implantation process described above in conjunction with FIG. 4D. The drain region 440a and the source region 440b can be transferred from a mask layer (not shown) that has a clear region corresponding thereto.

In FIG. 4H, a doped region 443 is formed adjacent to the source region 440b. The doped region 443 can be formed by any suitable process, such as ion implantation and/or a rapid thermal process (RTP) to activate the doped regions. The doped region 443 can be transferred from a mask layer (not shown) that has a clear region corresponding to the doped region 443.

In embodiments, dielectric materials, via plugs, metallic regions, and/or metallic lines can be formed over the gate electrode 420 for interconnection. The via plugs, metallic regions, and/or metallic lines can include materials such as tungsten, aluminum, copper, titanium, tantalum, titanium nitride, tantalum nitride, nickel silicide, cobalt silicide, other proper conductive materials, and/or combinations thereof. The via plugs, metallic regions, and/or metallic lines can be formed by any suitable processes, such as deposition, photolithography, and etching processes, and/or combinations thereof.

In a first embodiment of this application, an HV device can include a gate dielectric structure over a substrate. The gate dielectric structure has a first portion and a second portion. The first portion has a first thickness and is over a first well region of a first dopant type in the substrate. The second portion has a second thickness and is over a second well region of a second dopant type. The first thickness is larger than the second thickness. An isolation structure is disposed between the gate dielectric structure and a drain region disposed within the first well region. A gate electrode is disposed over the gate dielectric structure.

In a second embodiment of this application, a method of forming an HV device can include forming a gate dielectric structure over a substrate. The gate dielectric structure can have a first portion and a second portion. The first portion can have a first thickness and be over a first well region of a first dopant type in the substrate. The second portion can have a second thickness and be over a second well region of a second dopant type. The first thickness is larger than the second thickness. The method can include forming an isolation structure between the gate dielectric structure and a drain region disposed within the first well region. The method can also include forming a gate electrode over the gate dielectric structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A high voltage (HV) device comprising:
a gate dielectric structure over a substrate, the gate dielectric structure having a first portion and a second portion, the first portion having a first thickness and being disposed over a first well region of a first dopant type in the substrate, the second portion having a second thickness and being disposed over a second well region of a second dopant type, the first thickness being larger than the second thickness;
an isolation structure disposed between the gate dielectric structure and a drain region disposed within the first well region; and
a gate electrode disposed over the gate dielectric structure.

2. The HV device of claim 1, wherein the gate electrode at least partially extends over the isolation structure.

3. The HV device of claim 2, wherein the gate electrode extends proximately to a central region of the isolation structure.

4. The HV device of claim 1, wherein the isolation structure is thicker than the first portion of the gate dielectric structure.

5. The HV device of claim 1, wherein the second portion has a dimension along a channel direction of the HV device ranging from about 1.5 μm to about 2.5 μm, the first portion has a dimension along the channel direction of the HV device ranging about from 1.0 μm to about 1.5 μm, and the isolation structure has a dimension along the channel direction of the HV device ranging from about 1.3 μn to about 2.0 μm.

6. The HV device of claim 1, wherein the second thickness ranges from about 100 Angstrom (Å) to about 150 Å, the first thickness ranges from about 600 Å to about 690 Å, and the thickness of the isolation structure ranges from about 4,000 Å to about 5,000 Å.

7. A high voltage (HV) device comprising:
a gate dielectric structure over a substrate, the gate dielectric structure having a first portion and a second portion, the first portion having a first thickness and being disposed over a first well region of a first dopant type in the substrate, the second portion having a second thickness and being disposed over a second well region of a second dopant type, the first thickness being larger than the second thickness;
an isolation structure disposed between the gate dielectric structure and a drain region disposed within the first well region, wherein the isolation structure is thicker than the first portion of the gate dielectric structure; and
a gate electrode disposed over the gate dielectric structure, wherein the gate electrode at least partially extends over the isolation structure.

8. The HV device of claim 7, wherein the gate electrode extends proximately to a central region of the isolation structure.

9. The HV device of claim 7, wherein the second portion has a dimension along a channel direction of the HV device ranging from about 1.5 μm to about 2.5 μm, the first portion has a dimension along the channel direction of the HV device ranging about from 1.0 μm to about 1.5 μm, and the isolation structure has a dimension along the channel direction of the HV device ranging from about 1.3 μm to about 2.0 μm.

10. The HV device of claim 7, wherein, the second thickness ranges from about 100 Angstroms (Å) to about 150 Å, the first thickness ranges from about 600 Å to about 690 Å, and the thickness of the isolation structure ranges from about 4,000 Å to about 5,000 Å.

11. A method for forming a high voltage (HV) device, the method comprising:
forming a gate dielectric structure over a substrate, the gate dielectric structure having a first portion and a second portion, the first portion having a first thickness and being disposed over a first well region of a first dopant type in the substrate, the second portion having a second thickness and being disposed over a second well region of a second dopant type, the first thickness being larger than the second thickness;
forming an isolation structure between the gate dielectric structure and a drain region disposed within the first well region; and
forming a gate electrode over the gate dielectric structure.

12. The method of claim 11, wherein the gate electrode at least partially extends over the isolation structure.

13. The method of claim 12, wherein the gate electrode extends proximately to a central region of the isolation structure.

14. The method of claim 11, wherein forming the gate dielectric structure comprises:
forming at least one gate dielectric material over the substrate;
forming a patterned mask layer over the at least one gate dielectric material; and
implanting ions, by using the patterned mask layer, to adjust a threshold voltage of the HV device.

15. The method of claim 14, further comprising:
removing a portion of the at least one gate dielectric material, by using the patterned mask layer, so as to form the first portion of the gate dielectric structure;
forming the second portion of the gate dielectric structure over the substrate; and
removing the patterned mask layer.

16. The method of claim 11, wherein the isolation structure is thicker than the first portion of the gate dielectric structure.

17. The method of claim 11, wherein the second portion has a dimension along a channel direction of the HV device ranging from about 1.5 μm to about 2.5 μm, the first portion has a dimension along the channel direction of the HV device ranging about from 1.0 μm to about 1.5 μm, and the isolation structure has a dimension along the channel direction of the HV device ranging from about 1.3 μm to about 2.0 μm.

18. The method of claim 11, wherein the second thickness ranges from about 100 Å to about 150 Å, the first thickness ranges from about 600 Å to about 690 Å, and the thickness of the isolation structure ranges from about 4,000 Å to about 5,000 Å.
